(19) United States
(12) Patent Application Publication
(10) Pub. No.: US 2025/0297403 A1
(43) Pub. Date: Sep. 25, 2025

(54) METHOD FOR GROWING SINGLE-CRYSTAL SILICON, METHOD FOR PRODUCING SILICON WAFER, AND SINGLE-CRYSTAL PULLING DEVICE

(71) Applicant: SUMCO CORPORATION, Tokyo (JP)

(72) Inventors: Wataru SUGIMURA, Tokyo (JP); Ryusuke YOKOYAMA, Tokyo (JP); Hideki SAKAMOTO, Tokyo (JP); Jun FUJISE, Tokyo (JP)

(73) Assignee: SUMCO CORPORATION, Tokyo (JP)

(21) Appl. No.: 18/866,154

(22) PCT Filed: Mar. 31, 2023
(86) PCT No.: PCT/JP2023/013656

§ 371 Date: Nov. 15, 2024

(30) Foreign Application Priority Data
May 19, 2022 (JP) 2022-082329

(51) Int. Cl. C30B 15/14; C30B 29/06; C30B 30/04

(52) U.S. Cl. CPC C30B 15/14; C30B 29/06; C30B 30/04

(57) ABSTRACT

There is provided a method for growing monocrystalline silicon using a monocrystal pull-up apparatus that includes: a chamber; a crucible where silicon melt is stored; a heater configured to heat the silicon melt; a heat shield arranged above the crucible in a manner to surround monocrystalline silicon pulled up from the silicon melt; and an inert gas supply unit configured to supply an inert gas to pass through between the monocrystalline silicon and the heat shield, the method including: pulling up the monocrystalline silicon while applying a horizontal magnetic field to the silicon melt, in which the heat shield is arranged such that a center axis thereof vertically passing through a center position of an opening of the heat shield is displaced from a vertical rotation center axis of the crucible in a direction different from a magnetic-field application direction in a magnetic-field center portion of the horizontal magnetic field.

### TECHNICAL FIELD

The present invention relates to a method for growing monocrystalline silicon, a method for producing a silicon wafer, and a monocrystal pull-up apparatus.

### BACKGROUND ART

The Czochralski method is known as a method for producing monocrystalline silicon. In recent years, the so-called MCZ method has been widely used in which monocrystalline silicon is grown while a horizontal magnetic field is applied to a silicon melt. When a horizontal magnetic field is applied to a silicon melt using the MCZ method, either one of convection modes is initially formed: a mode in which a clockwise convection C1 predominates in a crucible 3 as illustrated in FIG. 1A (hereinafter referred to as a clockwise vortex mode); and a mode in which a counterclockwise convection C2 predominates in the crucible 3 as illustrated in FIG. 1B (hereinafter referred to as a counterclockwise vortex mode). In FIGS. 1A and 1B, a reference code MD indicates a magnetic-field application direction in a magnetic-field center portion.

The formed convection mode is at random either the clockwise vortex mode or the counterclockwise vortex mode. Accordingly, an oxygen concentration incorporated into crystal varies depending on the convection mode and furnace environments. In order to obtain ingots of monocrystalline silicon having a stable oxygen concentration, it is important to control the convection mode of the silicon melt during pulling up of the ingots of monocrystalline silicon. Various studies in consideration of this have been made for controlling the convection mode of the silicon melt in the crucible.

Patent Literature 1 discloses a method for eliminating variation in oxygen concentration caused by two convection modes by stably selecting one of the convection modes. Specifically, the convection mode is fixed to one of the two convection modes by changing a cutout of a heat shield to make a flow speed of an inert gas uneven, thereby inhibiting variation in oxygen concentration between ingots of monocrystalline silicon.

Patent Literature 2 discloses a method for inhibiting variation in oxygen concentration between ingots of monocrystalline silicon by fixing the convection mode to one of the two convection modes by displacing a position of a rotation center axis of a crucible from a position of a pull-up shaft to displace a center axis of thermal distribution of a silicon melt from a center axis of each ingot of monocrystalline silicon to be grown.

Patent Literature 3 discloses a method for inhibiting the variation in oxygen concentration between ingots of monocrystalline silicon by forming a local cutout in a heat shield, forming an oval opening in the heat shield, or the like to change a flow rate of an inert gas in a circumferential direction to fix the convection mode to one of the two convection modes.

### CITATION LIST

### Patent Literature(s)

Patent Literature 1: JP 2020-083717 A
Patent Literature 2: JP H04-31387 A
Patent Literature 3: JP 2019-151503 A

### SUMMARY OF THE INVENTION

### Problem(s) to be Solved by the Invention

However, according to the method of Patent Literature 1, sometimes, the flow speed of the inert gas changes only locally to fail to fix the convection mode.

In the method of Patent Literature 2, a step of bring a seed crystal into contact with the silicon melt becomes difficult, thereby decreasing probability that monocrystal can be grown, resulting in deterioration of a yield.

In the method of Patent Literature 3, due to uneven heat shield effects in the circumferential direction, a temperature distribution becomes large in the circumferential direction of crystal, causing crystal-twisting, so that the crystal may be impossible to pull up.

Further, in the methods of Patent Literatures 1 to 3, the oxygen concentration of the monocrystalline silicon to be grown is poorly controllable, and therefore, even when the convection mode is fixed, it is required to further adjust the pull-up conditions in order to obtain a desired oxygen concentration.

An object of the invention is to provide a method for growing monocrystalline silicon and capable of controlling an oxygen concentration while inhibiting variation in oxygen concentration between ingots of monocrystalline silicon, a method for producing a silicon wafer, and a monocrystal pull-up apparatus.

### Means for Solving the Problem(s)

According to an aspect of the invention, a method for growing monocrystalline silicon using a monocrystal pull-up apparatus, the monocrystal pull-up apparatus including: a chamber; a crucible in which silicon melt is stored; a heater configured to heat the silicon melt; a heat shield arranged above the crucible in a manner to surround monocrystalline silicon pulled up from the silicon melt; and an inert gas supply unit configured to supply an inert gas to pass through between the monocrystalline silicon and the heat shield, the method includes: pulling up the monocrystalline silicon while applying a horizontal magnetic field to the silicon melt, in which the heat shield is arranged such that a center axis thereof vertically passing through a center position of an opening of the heat shield is displaced from a vertical rotation center axis of the crucible in a direction different from a magnetic-field application direction in a magnetic-field center portion of the horizontal magnetic field.

In the method for growing monocrystalline silicon according to the above aspect, it is preferable that the heat shield is arranged such that the center axis of the heat shield is displaced from the rotation center axis of the crucible in a horizontal direction orthogonal to the magnetic-field application direction.

In the method for growing monocrystalline silicon, it is preferable that when a surface of the silicon melt viewed from above through the opening of the heat shield is divided into a first side and a second side in a horizontal direction orthogonal to the magnetic-field application direction with respect to a line passing through the center position of the opening and being parallel to the magnetic-field application direction, a surface area of a smaller side of the first and second sides is denoted as A and a surface area of a larger side thereof is denoted as B, the heat shield is arranged at a ratio A/B falling within a range from 0.3 to 0.96.

According to another aspect of the invention, a method for producing a silicon wafer includes: the method for growing monocrystalline silicon according to the above aspect; and cutting out a silicon wafer from the grown monocrystalline silicon.

According to still another aspect of the invention, a monocrystal pull-up apparatus includes: a chamber; a crucible in which silicon melt is stored; a heater configured to heat the silicon melt; a heat shield arranged above the crucible in a manner to surround monocrystalline silicon pulled up from the silicon melt; an inert gas supply unit configured to supply an inert gas to pass through between the monocrystalline silicon and the heat shield; and a magnetic-field applying unit configured to apply a horizontal magnetic field to the silicon melt in the crucible, in which the heat shield is arranged such that a center axis of the heat shield vertically passing through a center position of an opening of the heat shield is displaced from a vertical rotation center axis of the crucible in a direction different from a magnetic-field application direction in a magnetic-field center portion of the horizontal magnetic field.

In the monocrystal pull-up apparatus according to the above aspect, it is preferable that the heat shield is arranged such that the center axis of the heat shield is displaced from the rotation center axis of the crucible in a horizontal direction orthogonal to the magnetic-field application direction.

In the monocrystal pull-up apparatus according to the above aspect, it is preferable that when a surface of the silicon melt viewed from above through the opening of the heat shield is divided into a first side and a second side in the horizontal direction orthogonal to the magnetic-field application direction with respect to a line passing through the center position of the opening and being parallel to the magnetic-field application direction, a surface area of a smaller side of the first and second sides is denoted as A and a surface area of a larger side thereof is denoted as B, the heat shield is arranged at a ratio A/B falling within a range from 0.3 to 0.96.

### BRIEF DESCRIPTION OF DRAWINGS

FIG. 1A schematically illustrates a convection mode.

FIG. 1B schematically illustrates another convection mode.

FIG. 2 is a schematic cross-sectional view of a monocrystal pull-up apparatus according to an exemplary embodiment of the invention.

FIG. 3 is a schematic plan view of a heat shield according to an exemplary embodiment of the invention.

FIG. 4 is a graph showing a relationship between a gap distance and a flow speed of an inert gas over a surface of a silicon melt.

FIG. 5 is a schematic cross-sectional view illustrating a flow of an inert gas at the periphery of a crucible, oxygen evaporation, and the like.

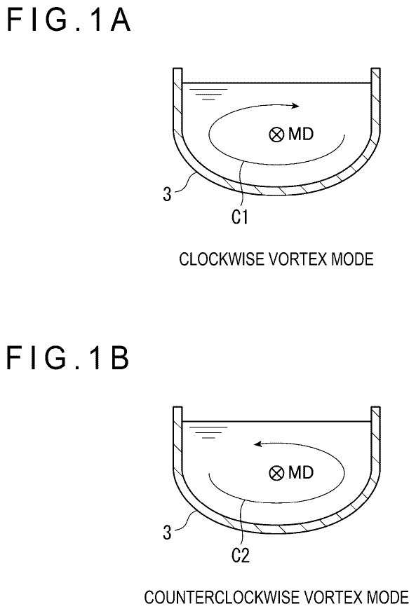

### DESCRIPTION OF EMBODIMENT(S)

### Configuration of Monocrystal Pull-Up Apparatus

A configuration of a monocrystal pull-up apparatus according to an exemplary embodiment of the invention will be described.

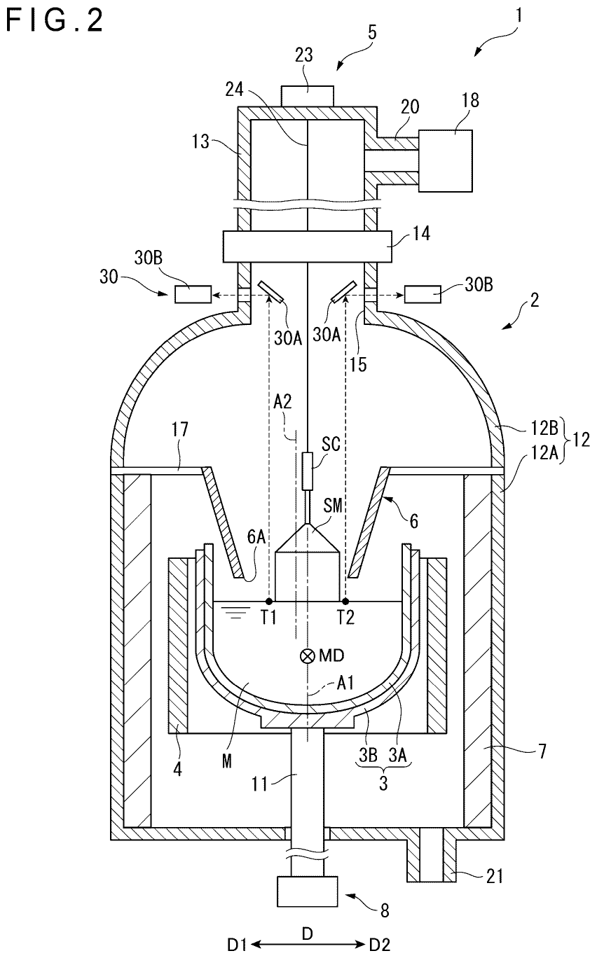

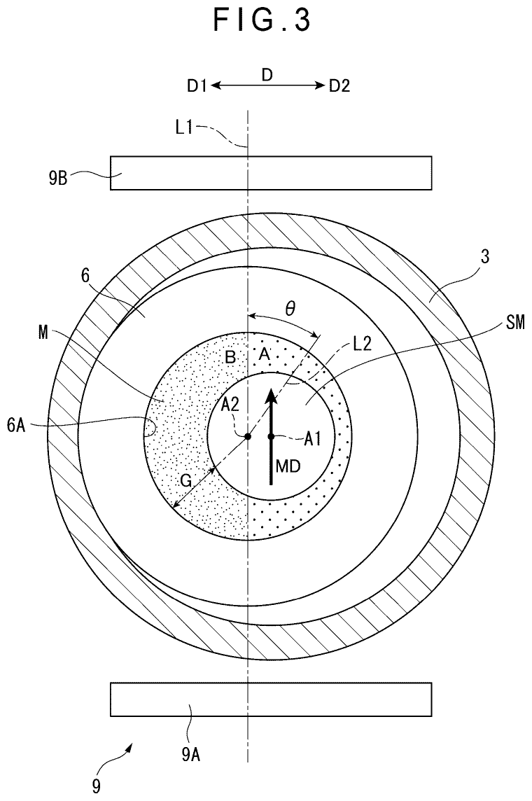

As illustrated in FIG. 2, a monocrystal pull-up apparatus 1 pulls up monocrystalline silicon SM while a horizontal magnetic field is applied to a silicon melt M by the MCZ method. The monocrystal pull-up apparatus 1 includes: a chamber 2; a crucible 3 that is arranged in the chamber 2 and in which the silicon melt M is stored; a heater 4; a pull-up unit 5 that pulls up the monocrystalline silicon SM; a heat shield 6 arranged above the crucible 3 in a manner to surround the monocrystalline silicon SM; a heat insulator 7; a crucible driver 8; a magnetic-field applying unit 9 that applies a horizontal magnetic field to the silicon melt M (see FIG. 3); and an inert gas supply unit 18 that supplies an inert gas to pass through between the monocrystalline silicon SM and the heat shield 6.

The crucible 3 has a double structure including a quartz crucible 3A and a graphite crucible 3B housing the quartz crucible 3A.

The crucible driver 8 has a support shaft 11 supporting the crucible 3 from below. The crucible driver 8 rotates and vertically moves the crucible 3 around a rotation center axis A1 at a predetermined speed.

The chamber 2 includes a main chamber 12 and a pull chamber 13 connected to an upper part of the main chamber 12. The main chamber 12 and the pull chamber 13 are connected to each other via a gate valve 14.

The main chamber 12 includes: a body 12A, where the crucible 3, heater 4, heat shield 6, and the like are arranged; and a cover 12B with which an upper side of the body 12A is covered. The body 12A has a hollow cylindrical shape. The cover 12B has an opening 15 through which an inert gas such as argon gas is introduced into the main chamber 12. A support 17 extending inward is provided between the body 12A and the cover 12B.

A pull chamber 13 has a gas inlet 20 through which the inert gas supplied from the inert gas supply unit 18 is introduced into the main chamber 12. A gas outlet 21, through which the gas in the main chamber 12 is sucked and discharged when a vacuum pump (not illustrated) is driven, is provided at a lower part of the body 12A of the main chamber 12.

The inert gas having been introduced into the chamber 2 from the gas inlet 20 flows downward between the growing monocrystalline silicon SM and the heat shield 6. Then, the inert gas passes through a space between a lower end of the heat shield 6 and a liquid surface of the silicon melt M, then toward an outside of the heat shield 6, and further toward an outside of the crucible 3. Subsequently, the inert gas flows downward along the outside of the crucible 3 to be discharged from the gas outlet 21.

The heater 4 is of a resistance heating type and heats the silicon melt M. The heater 4 is arranged surrounding the crucible 3 inside the heat insulator 7. The entire heater 4 is formed to be hollow cylindrical.

The pull-up unit 5 includes: a pull-up shaft 24 on which a seed crystal SC is attached at one end; and a pull-up driver 23 that rotates and vertically moves the pull-up shaft 24.

The respective center axes of the chamber 2 and the heater 4 are aligned with the rotation center axis A1 of the crucible 3. The rotation center axis A1 of the crucible 3 is aligned with the center of the pull-up shaft 24.

The heat insulator 7 has a hollow cylindrical shape and a predetermined thickness in a radial direction. The heat insulator 7 is arranged outside the heater 4 and inside the chamber 2.

The heat shield 6 shields the growing monocrystalline silicon SM from high temperature radiation heat from the silicon melt M in the crucible 3, the heater 4, and a side wall of the crucible 3. The heat shield 6 inhibits outward heat diffusion from a solid-liquid interface, which is an interface on which crystal grows, and a vicinity thereof, thus controlling a vertical temperature gradient of a center portion and an outer peripheral portion of the monocrystalline silicon SM.

In addition, the heat shield 6 functions as a flow straightening cylinder through which evaporation substances from the silicon melt M together with an inert gas introduced from an upper part of the furnace are discharged to the outside of the furnace.

An upper end of the heat shield 6 is supported by the support 17 of the chamber 2. The heat shield 6 is shaped to be a hollow circular truncated cone whose diameter decreases toward a lower end thereof. Since the heat shield 6 is shaped to be a hollow circular truncated cone, the lower end of the heat shield 6 has an opening 6A smaller in diameter than that in the upper end of the heat shield 6. The center position of the opening 6A coincides with a center axis A2 of the heat shield 5.

The shape of the heat shield 6 is not limited to the shape described above. For example, the heat shield 6 may have the shape of a hollow circular truncated cone including a hollow cylindrical body and a flange-shaped protrusion that protrudes inward from the entire lower end of the body, the diameter of the protrusion decreasing toward a lower end thereof.

As illustrated in FIG. 3, the heat shield 6 is arranged such that the center axis A2, which vertically passes through the center position of the opening 6A of the heat shield 6, is arranged to be displaced from the vertical rotation center axis A1 in the horizontal direction orthogonal to a magnetic-field application direction MD in the magnetic-field center portion of the horizontal magnetic field.

That is, the center axis A2 of the heat shield 6 is not aligned with the rotation center axis A1, whereby a gap distance G between an outer circumferential surface of the monocrystalline silicon SM to be pulled up and the opening 6A of the heat shield 6 is non-uniform in a circumferential direction of the heat shield 6.

The gap distance G is a distance between the monocrystalline silicon SM and the opening 6A of the heat shield 6 on a straight line L2. The straight line L2 passes through the center position of the opening 6A of the heat shield 6 (the center axis A2 of the heat shield 6) and any position of the opening 6A in the circumferential direction. It should be noted that a displacement amount of the heat shield 6 is emphasized in order to explain the arrangement of the heat shield 6.

Specifically, when a surface of the silicon melt M viewed from above through the opening 6A is divided into a first side D1 and a second side D2 in a horizontal direction D with respect to a line L1 passing through the center position of the opening 6A and being parallel to the magnetic-field application direction MD in the magnetic-field center portion of the horizontal magnetic field, a surface area of a smaller side of the first and second sides is denoted as A and a surface area of a larger side thereof is denoted as B. The heat shield 6 is arranged at A/B (a ratio between the area A and the area B) falling within a range from 0.3 to 0.96. In the following description, a region with the smaller area A is referred to as an A region and a region with the larger area B is referred to as a B region.

The magnetic-field applying unit 9 includes a first magnetic body 9A and a second magnetic body 9B each in a form of a solenoid coil. The first and second magnetic bodies 9A and 9B are provided outside the chamber 2 in a manner to face each other across the crucible 3. (In FIG. 3, the illustration of the chamber 2 is omitted and the magnetic-field applying unit 9 is illustrated near the crucible 3.) The magnetic-field applying unit 9 is thus arranged such that the magnetic-field application direction MD in the magnetic-field center portion horizontally passes through the rotation center axis A1 of the crucible 3. That is, the magnetic-field center portion lies in the horizontal direction in the rotation center axis A1 of the crucible 3.

### Method for Growing Monocrystalline Silicon

Next, a description will be given on a method for growing monocrystalline silicon by using the above-described monocrystal pull-up apparatus 1.

First, an inert gas is introduced into the chamber 2 under no application of the horizontal magnetic field, and the chamber 2 is kept in an inert gas atmosphere under reduced pressure. Under such a condition, while the crucible 3 is rotated, solid raw materials such as polycrystalline silicon stored in the crucible 3 are melt by heating with the heater 4 to generate the silicon melt M.

Next, while the inert gas continues to be introduced, the magnetic-field applying unit 9 is driven to apply the horizontal magnetic field. At this time, the gap distance G is non-uniform in the circumferential direction.

Next, under the preset process conditions, the seed crystal SC is dipped into the silicon melt M and then the monocrystalline silicon SM is pulled up.

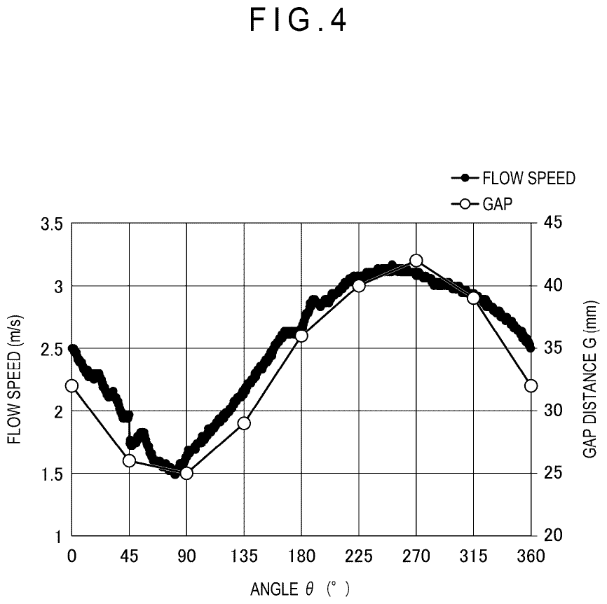

A description will be given on a relationship between the gap distance G and a flow speed of the inert gas over a surface of the silicon melt. FIG. 4 is a graph showing the relationship between the gap distance G and the flow speed of the inert gas over the surface of the silicon melt. In the graph of FIG. 4, the abscissa shows an angle θ formed by the straight line L2 in FIG. 3, while the ordinate shows the flow speed of the inert gas over the silicon melt surface and the gap distance G. The gap distance G is the maximum when the angle θ formed by the straight line L2 is 270 degrees.

According to the inventors' verification, as shown in FIG. 4, there is a relationship where the larger the gap distance G, the higher the flow speed of the inert gas. Accordingly, when the gap distance G is non-uniform in the circumferential direction, the flow speed of the inert gas over the silicon melt surface is also non-uniform in the circumferential direction.

Next, a description will be given on controlling the oxygen concentration of monocrystalline silicon with use of non-uniformity of the flow speed of the inert gas. The method for growing the monocrystalline silicon of the invention controls the oxygen concentration of monocrystalline silicon using fixation of the convection mode and the relationship between the flow speed of the inert gas and oxygen evaporation.

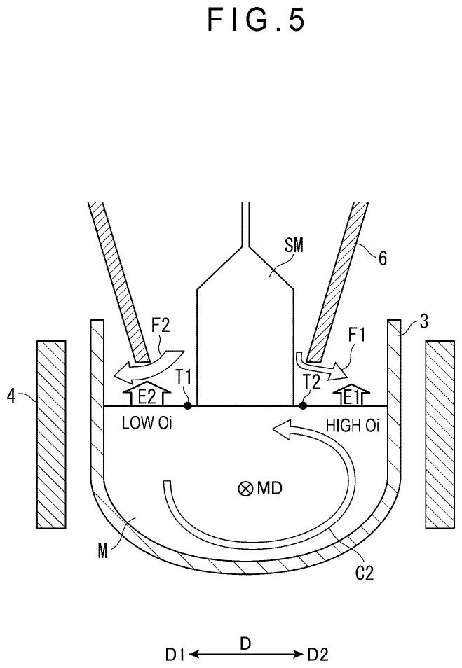

First, a description will be given on fixation of the convection mode. FIG. 5 is a schematic cross-sectional view illustrating the flow of the inert gas at the periphery of the crucible, oxygen evaporation, and the like.

When the flow speed of the inert gas is non-uniform in the circumferential direction, temperature distribution around the crucible is also non-uniform. Specifically, when the heat shield 6 is arranged to be displaced leftward (a side of D1 in FIG. 5), the right side (a side of D2 in FIG. 5) in FIG. 3 is the A region having the smaller area and the left side is the B region having the larger area, and therefore the flow rate of the inert gas flowing on the right side is decreased. This reduces the heat extraction effect on the right side of crucible 3, so that a temperature in the right side of the crucible is relatively higher than a temperature in the left side of the crucible. As a result, an upward flow in the right side of the silicon melt M becomes dominant, so that the convection mode becomes a counterclockwise vortex mode (reference code C2).

Conversely, the convection mode can be made a clockwise vortex mode by placing the heat shield 6 on the right side. The convection mode can be thus fixed according to the direction where the heat shield 6 is displaced.

Next, a description will be given on a relationship between the flow speed of the inert gas and the oxygen evaporation.

As compared with the B region in FIG. 3, since the flow speed of the inert gas in the A region is low (reference numeral F1 in FIG. 5), an amount of oxygen evaporating from the surface of the silicon melt is decreased (reference numeral E1). In contrast, in the B region as compared with the A region, since the flow speed of the inert gas is high (reference numeral F2 in FIG. 5), the amount of oxygen evaporating from the surface of the silicon melt is increased (reference numeral E2).

This is because of a positive correlation between the flow speed of the inert gas directly above the silicon melt and the evaporation amount of oxygen at that location. Due to the small evaporation amount of oxygen, the oxygen amount in the silicon melt in the A region is relatively larger than that in the B region.

At this time, since the convection mode of the silicon melt M is fixed to the counterclockwise vortex mode, the oxygen concentration incorporated into the monocrystalline silicon SM is higher than the oxygen concentration of the monocrystalline silicon grown in the middle of the chamber without displacement of the heat shield.

It should be noted that an increased amount of the oxygen concentration is controllable in a simple way by controlling the ratio A/B without adjusting the pull-up conditions. The oxygen concentration is further adjustable by changing the process conditions such as the rotation speed of the crucible, the rotation speed of the crystal, and the flow rate of the inert gas.

As described above, the oxygen concentration of the monocrystalline silicon has been controlled by displacing the heat shield 6 to make the flow speed of the inert gas non-uniform in the circumferential direction.

### Method for Producing Monocrystalline Silicon

A final silicon wafer is producible by cutting out a silicon wafer using a wire saw (not illustrated) from an ingot of monocrystalline silicon SM having been grown by the above-described method for growing monocrystalline silicon, and subjecting the silicon wafer to general wafer-production processing steps such as chamfering, polishing, and cleaning.

According to the above exemplary embodiment, the convection mode can be fixed to one of the convection modes by arranging the heat shield 6 in the crucible 3 such that the center position of the opening 6A of the heat shield 6 is displaced from the rotation center axis A1 of the crucible 3 in the horizontal direction D. Moreover, the oxygen concentration of the monocrystalline silicon SM can be controlled by adjusting the displacement amount of the heat shield 6.

In the above exemplary embodiment, the heat shield 6 is displaced in the horizontal direction D orthogonal to the magnetic-field application direction MD in the magnetic-field center portion of the horizontal magnetic field. However, the direction where the heat shield 6 is displaced may be an oblique direction to the horizontal direction D orthogonal to the magnetic-field application direction MD in the magnetic-field center portion of the horizontal magnetic field. Specifically, the heat shield 6 may be arranged such that the center axis A2 of the heat shield 6 is displaced from the rotation center axis A1 of the crucible 3 in a different direction from a direction along the magnetic-field application direction MD in the magnetic-field center portion of the horizontal magnetic field.

Displacing the heat shield 6 in an oblique direction makes it possible to change the ratio A/B more variously and finely tune the oxygen concentration of the monocrystalline silicon SM.

A cross-sectional shape of the heat shield 6 in a plane orthogonal to the center axis A2 is circular. The cross-sectional shape of the heat shield 6 needs not necessarily be a perfect circle. In view of dimensional tolerances and other factors in producing the heat shield 6, the cross-sectional shape of the heat shield 6 can be regarded as circular if the eccentricity is 0.22 or less.

### EXAMPLES

The position of the heat shield was displaced in the horizontal direction D orthogonal to the magnetic-field application direction MD in the magnetic-field center portion of the horizontal magnetic field, thereby changing a value of the ratio A/B between the area A and the area B. Under this situation, ingots of monocrystalline silicon were grown and compared with each other in terms of the oxygen concentration.

Table 1 shows seven conditions of the A/B ratio to be changed.

Under these conditions, ingots of monocrystalline silicon each having a diameter of 300 mm and a crystal length of 2,000 mm were grown. 100 ingots of monocrystalline silicon were grown for each condition.

TABLE 1

| | | | Oxygen concentration |
|---|---|---|---|
| | | Fixation rate of | (ratio to average value |
| Condition | A/B | convection mode (%) | in Comp. 1) |
| Comparative 1 | 1 | 50 | 0.80~1.20 |
| Comparative 2 | 0.97 | 70 | 0.95~1.25 |
| Example 1 | 0.96 | 100 | 1.30 |
| Example 2 | 0.80 | 100 | 1.35 |
| Example 3 | 0.50 | 100 | 1.40 |
| Example 4 | 0.30 | 100 | 1.50 |
| Comparative 3 | 0.25 | 100 | Crystal contacted with |
| | | | heat shield. |

For each condition, a fixation rate of the convection mode and the oxygen concentration at a position of 1,000 mm below the top of the grown ingots of monocrystalline silicon were measured by Fourier Transform Infrared Spectroscopy (FTIR) and the results are shown in Table 1.

Two positions T1 and T2 on the surface of the silicon melt (see FIG. 5) were measured using a temperature sensor 30 (see FIG. 2). Whether the convection mode was the clockwise vortex mode or the counterclockwise vortex mode was determined depending on which temperature of those at the two positions was larger. The temperature sensor 30 includes a pair of reflectors 30A and a pair of radiation thermometers 30B and measures a temperature of the surface of the silicon melt M.

Rendering an average value of oxygen concentrations in Comparative 1 (A/B=1) as a reference value, a ratio between the reference value and an average value of the minimum value to the maximum value of oxygen concentrations of 100 ingots of monocrystalline silicon in each condition was shown in Table 1.

The ratio A/B needs to be 0.96 or less in order to fix the convection mode as seen from Table 1. At the ratio A/B of less than 0.3, monocrystalline silicon is put into contact with the heat shield, so that monocrystalline silicon cannot continue to be grown. At the ratio A/B in a range from 0.3 to 0.96, the convection mode can be fixed to one of the convection modes and the oxygen concentration of the monocrystalline silicon can be higher than that in Comparative 1.

That is, it has been found that the convection mode can be more reliably fixed to one of the convection modes by arranging the heat shield 6 so that the value of the ratio A/B between the area A and the area B falls within a range from 0.3 to 0.96.

Moreover, it is only sufficient to vary the rotation speed of the crucible and the rotation speed of the monocrystalline silicon in order to grow monocrystalline silicon to have a desired oxygen concentration.

### EXPLANATION OF CODES

1 . . . monocrystalline pull-up apparatus, 2 . . . chamber, 3 . . . crucible, 4 . . . heater, 5 . . . pull-up unit, 6 . . . heat shield, 6A . . . opening, 7 . . . heat insulator, 9 . . . magnetic-field applying unit, 18 . . . inert gas supply unit, 23 . . . pull-up driver, 24 . . . pull-up shaft, A1 . . . rotation center axis, A2 . . . center axis, D . . . horizontal direction orthogonal to a magnetic-field application direction in a magnetic-field center portion of a horizontal magnetic field, M . . . silicon melt, MD . . . magnetic-field application direction in the magnetic-field center portion of the horizontal magnetic field, SC . . . seed crystal, SM . . . monocrystalline silicon

1. A method for growing monocrystalline silicon using a monocrystal pull-up apparatus, the monocrystal pull-up apparatus comprising:
a chamber;
a crucible in which a silicon melt is stored;
a heater configured to heat the silicon melt;
a heat shield arranged above the crucible in a manner to surround monocrystalline silicon pulled up from the silicon melt; and
an inert gas supply unit configured to supply an inert gas to pass through between the monocrystalline silicon and the heat shield,
the method comprising:
pulling up the monocrystalline silicon while applying a horizontal magnetic field to the silicon melt, wherein
the heat shield is arranged such that a center axis of the heat shield vertically passing through a center position of an opening of the heat shield is displaced from a vertical rotation center axis of the crucible in a direction different from a magnetic-field application direction in a magnetic-field center portion of the horizontal magnetic field.

2. The method for growing monocrystalline silicon according to claim 1, wherein the heat shield is arranged such that the center axis of the heat shield is displaced from the rotation center axis of the crucible in a horizontal direction orthogonal to the magnetic-field application direction.

3. The method for growing monocrystalline silicon according to claim 1, wherein when a surface of the silicon melt viewed from above through the opening of the heat shield is divided into a first side and a second side in a horizontal direction orthogonal to the magnetic-field application direction with respect to a line passing through the center position of the opening and being parallel to the magnetic-field application direction, a surface area of a smaller side of the first and second sides is denoted as A and a surface area of a larger side thereof is denoted as B, the heat shield is arranged at a ratio A/B falling within a range from 0.3 to 0.96.

4. A method for producing a silicon wafer, comprising:
the method for growing monocrystalline silicon according to claim 3; and
cutting out a silicon wafer from the grown monocrystalline silicon.

5. A monocrystalline pull-up apparatus comprising:
a chamber;
a crucible in which a silicon melt is stored;
a heater configured to heat the silicon melt;
a heat shield arranged above the crucible in a manner to surround monocrystalline silicon pulled up from the silicon melt;
an inert gas supply unit configured to supply an inert gas to pass through between the monocrystalline silicon and the heat shield; and
a magnetic-field applying unit configured to apply a horizontal magnetic field to the silicon melt in the crucible, wherein
the heat shield is arranged such that a center axis of the heat shield vertically passing through a center position of an opening of the heat shield is displaced from a vertical rotation center axis of the crucible in a direction different from a magnetic-field application direction in a magnetic-field center portion of the horizontal magnetic field.

6. The monocrystalline pull-up apparatus according to claim 5, wherein the heat shield is arranged such that the center axis of the heat shield is displaced from the rotation center axis of the crucible in a horizontal direction orthogonal to the magnetic-field application direction.

7. The monocrystalline pull-up apparatus according to claim 5 or 6, wherein when a surface of the silicon melt viewed from above through the opening of the heat shield is divided into a first side and a second side in the horizontal direction orthogonal to the magnetic-field application direction with respect to a line passing through the center position of the opening and being parallel to the magnetic-field application direction, a surface area of a smaller side of the first and second sides is denoted as A and a surface area of a larger side thereof is denoted as B, the heat shield is arranged at a ratio A/B falling within a range from 0.3 to 0.96.
